(19) United States
(12) Patent Application Publication
(10) Pub. No.: US 2019/0341506 A1
(43) Pub. Date: Nov. 7, 2019

(54) DOPING AND PASSIVATION FOR HIGH EFFICIENCY SOLAR CELLS

(71) Applicant: Colorado State University Research Foundation, Fort Collins, CO (US)

(72) Inventors: Walajabad S. Sampath, Fort Collins, CO (US); Amit H. Munshi, Fort Collins, CO (US); Adam H. Danielson, Loveland, CO (US); Kurt L. Barth, Fort Collins, CO (US)

(73) Assignee: Colorado State University Research Foundation, Fort Collins, CO (US)

(21) Appl. No.: 16/404,479

(22) Filed: May 6, 2019

Related U.S. Application Data
(60) Provisional application No. 62/668,006, filed on May 7, 2018.
(60) Provisional application No. 62/668,014, filed on May 7, 2018.

(51) Int. Cl. H01L 31/0216; H01L 31/0445; H01L 31/0296; H01L 31/18; H01L 31/0687; H01L 31/0224

(52) U.S. Cl. CPC H01L 31/02167; H01L 31/0445; H01L 31/02966; H01L 31/02963; H01L 31/0687; H01L 31/022466; H01L 31/1832; H01L 31/1868

(57) ABSTRACT

The present disclosure relates to thin-film solar cells with improved efficiency and methods for producing thin-film solar cells having increased efficiency. In certain embodiments, thin-film solar cells having an efficiency of over 21%, over 20%, over 19%, over 15%, over 10%, etc. has been obtained using the methods of the disclosure. In certain aspects, the methods of the disclosure use passivation, passivating oxides, and/or doping treatments in increase the efficiency of the thin-film solar cells; e.g., CdTe-based thin-film solar cells.

### CROSS-REFERENCE TO RELATED APPLICATIONS

The present application claims the benefit of the filing date under 35 U.S.C. § 119(e) of U.S. Application No. 62/668,006, filed May 7, 2018 and U.S. Application No. 62/668,014, filed May 7, 2018, the contents of which are herein incorporated by reference in their entireties.

### STATEMENT OF GOVERNMENT SUPPORT

The present invention was made with government support under grant DE-EE0008177 awarded by the United States Department of Energy. The government has certain rights in the present disclosure.

### FIELD OF THE DISCLOSURE

The present disclosure relates generally to thin-film solar cells. In particular, the present disclosure relates to a method increasing efficiency of a semiconducting/absorber layer.

### BACKGROUND OF THE DISCLOSURE

Sustainable energy resources have presented many opportunities and challenges in modern society. One source of sustainable energy can be found in solar cells. Solar cells are an electrical device that can be used to convert light energy into electricity. Solar cells can be used to produce electrical characteristics, such as current, voltage, and resistance, in varying ranges when exposed to light based on the components within the cell. Thin-film solar cells are a second generation form of the solar cell which can be made by depositing one or more thin layers on a substrate. Thin-film solar cells can significantly reduce the cost of energy when compared to coal, nuclear, gas, and diesel energy sources. Thin-film semi-conductor technology is currently being used world-wide and has been commercialized at the gigawatts (GW)-per-year scale, with nearly 17.5 GWs installed globally. However, while thin-film solar cells require only a fraction of the semiconductor materials required by their predecessors, the thin-film solar cells tend to be less efficient than the conventional, first-generation solar cells.

Solar cells can be made of thin-film semi-conductor materials. Various improvements have been made to thin-film solar cells over the past several decades. Specifically efficiency of thin-film solar cells has increased from about 16% to about 18% in just two years from 2014 to 2016. Commercially available solar cells generate energy at about 18% efficiency with about 28 mA/cm² short-circuit current and 850 mV open-circuit voltage.

### SUMMARY OF THE DISCLOSURE

One aspect of the disclosure is directed to a thin-film solar cell with improved efficiency, the thin-film solar cell comprising: a semiconducting/absorber layer; at least one p+ layer; and one or more oxide layers passivated onto at least one surface of the semiconducting/absorber layer. In certain embodiments, the thin-film solar cell exhibits an efficiency of at least 10%.

In another aspect of the disclosure, thin-film solar cells with improved efficiency are provided wherein at least one of the oxide layers is passivated onto the front-surface of the semiconducting/absorber layer.

In certain embodiments, the at least one oxide layer on the front-surface of the semiconducting/absorber layer is formed from aluminum oxide (Al₂O₃). In certain embodiments, the at least one oxide layer on the front-surface of the semiconducting/absorber layer is about 2 nanometers (nm) to 10 nm in thickness.

In another aspect of the disclosure, thin-film solar cells with improved efficiency are provided which comprise at least one additional oxide layer in addition to the at least one oxide layer on the front-surface of the semiconducting/absorber layer. In certain embodiments, the at least one additional oxide layer is passivated onto the back-surface of the semiconducting/absorber layer.

In certain embodiments, the at least one oxide layer on the back-surface of the semiconducting/absorber layer is aluminum oxide (Al₂O₃). In certain embodiments, the at least one oxide layer on the back-surface of the semiconducting/absorber layer is about 2 nm to 100 nm in thickness.

In certain embodiments, the semiconducting/absorber layer may be formed from a material comprising cadmium telluride (CdTe) and/or a ternary alloy of CdTe comprising CdSeTe, CdMgTe, CdZnTe or CdHgTe.

In other embodiments, the at least one oxide layer may be formed from a material selected from the group consisting of copper aluminum oxide (CuAlO₃), strontium copper oxide (SrCu₂O₂), copper oxide (Cu₂O), magnesium zinc oxide (MgZnO), aluminum oxide (Al₂O₃), and tin oxide (SnO₂).

In yet other embodiments, prior to passivating the at least one oxide layer onto at least one surface of the semiconducting/absorber layer, the at least one surface of the semiconducting/absorber layer is doped using a dopant selected from the group consisting of nitrogen, phosphorus, arsenic, antimony, and bismuth, and copper. In certain embodiments, the semiconducting/absorber layer is doped with copper. By way of example, the semiconducting/absorber layer may be doped to produce both a front-surface contact and a back-surface contact.

In yet other embodiments, thin-film solar cells with improved efficiency may further comprising a telluride layer disposed beneath the semiconducting/absorber layer.

In yet other embodiments, thin-film solar cells with improved efficiency may comprise a plurality of oxide layers. In certain embodiments, at least one of the plurality of oxide layers are formed from magnesium zinc oxide (MgZnO). In other embodiments, the plurality of oxide layers produce a high-band gap cell, a mid band-gap cell, and a low-band gap cell.

Other aspects of the disclosure are directed to a method for producing a thin-film solar cell with improved efficiency as described herein, the method comprising: providing an semiconducting bulk material; depositing one or more one oxide layers onto at least one surface of the semiconducting bulk material; passivating the deposited one or more oxide layer; and doping the semiconducting bulk material with a dopant to thereby form a semiconducting/absorber layer. In certain embodiments, the doping of the semiconducting bulk material after depositing and passivating the one or more oxide layers produces a thin-film solar cell with an efficiency of at least 10%. In certain embodiments, at least one of the oxide layers is passivated onto the front-surface of the semiconducting material.

These and other aspects and iterations of the disclosure are described in more detail below.

### BRIEF DESCRIPTION OF THE DRAWINGS

Implementations of the present technology will now be described, by way of example only, with reference to the attached figures, wherein:

FIGS. 1A and 1B illustrate graphs of photoluminescence intensity;

FIG. 2 is a graph illustrating open-circuit voltage and efficiency within a treated solar cell;

FIG. 3A illustrates an exemplary single-junction solar cell in accordance with the present disclosure;

FIG. 3B illustrates an exemplary multi-junction solar cell in accordance with the present disclosure;

FIG. 4 is a schematic diagram indicating device efficiency improvements; and

FIG. 5 is an enlarged view of the 2017 CdTe device and corresponding voltage chart.

### DETAILED DESCRIPTION

Disclosed herein is a method for producing thin-film solar cells having increased efficiency, and thin film solar cells produced by such methods. In certain aspects, the methods of the disclosure use passivation, passivating oxides, and/or doping treatments in increase the efficiency of the thin-film solar cells; e.g., CdTe-based thin-film solar cells. In certain embodiments, thin-film solar cells having an efficiency of over 21%, over 20%, over 19%, over 15%, over 10%, etc. has been obtained using the methods of the disclosure.

As described in more detail herein, in certain aspects, the disclosure provides a thin-film solar cell with improved efficiency. In certain embodiments, the thin-film solar cell includes: a semiconducting/absorber layer; at least one p+ layer; and at least one oxide layer passivated onto at least one surface of the semiconducting layer. In certain embodiments, the thin-film solar cell exhibits an efficiency of at least 10%, at least 15%, at least 19%, at least 20%, etc.

In certain aspects of the disclosure, it has been found that use of an oxide such as Al₂O₃ provides beneficial performance, stability, and manufacturability as compared to more traditional oxides such as MgZnO, particularly when used at the front-interface of the semiconducting layer. As such, in certain embodiments of the disclosure, the thin-film solar cell includes one or more oxide layers passivated onto at least one surface of the semiconducting layer, wherein at least one of the oxide layers is passivated onto the front-surface of the semiconducting/absorber layer, and the at least one oxide layer on the front-surface of the semiconducting/absorber layer is formed from aluminum oxide (Al₂O₃).

In certain embodiments, the semiconducting/absorber layer may be formed from a material comprising cadmium telluride (CdTe), copper indium gallium diselenide (CIGS), or amorphous thin-film silicon (a-Si, TF-Si). By way of non-limiting example, the semiconducting/absorber layer may be formed from a material comprising cadmium telluride (CdTe), and/or a ternary alloy of CdTe, such as CdSeTe, CdMgTe, CdZnTe or CdHgTe.

In certain embodiments, the oxide layer may be formed from a material comprising copper aluminum oxide (CuAlO₃), strontium copper oxide (SrCu₂O₂), copper oxide (Cu₂O), magnesium zinc oxide (MgZnO), aluminum oxide (Al₂O₃), tin oxide (SnO₂), etc. In certain aspects, prior to passivating the oxide layer onto at least one surface of the semiconducting layer, the semiconducting layer may be doped, and the dopant may be selected from, e.g., nitrogen, phosphorus, arsenic, antimony, bismuth, copper, etc.

In certain aspects, the at least one surface of the semiconducting/absorber layer is a front-surface or a back-surface. In certain aspects, an oxide layer can be passivated on to the front-surface only, the back-surface only, or both the front-surface and the back-surface of the semiconducting/absorber layer. In certain aspects, the oxide layer passivated onto the front and back-surfaces of the semiconducting/absorber material can be the same oxide. In other aspects, the oxide layer passivated onto the front and back surfaces of the semiconducting/absorber material can be different oxides. In certain aspects, the oxide layer on the front-surface, the back-surface, or both the front and the back-surfaces of the semiconducting/absorber layer can be from less than about 1 nanometer (nm) in thickness to about 200 nm in thickness, from about 2 nanometers (nm) in thickness to about 120 nm in thickness, etc.

Other aspects of the disclosure provide a method for producing a thin-film solar cell with improved efficiency. In certain embodiments, the method includes providing an semiconducting bulk material; depositing at least one oxide layer onto at least one surface of the semiconducting material; passivating the deposited at least one oxide layer; and doping the semiconducting bulk material with a dopant to thereby form the semiconducting/absorber layer; wherein the doping of the semiconducting bulk material after depositing and passivating the at least one oxide layer thereby increases efficiency of the thin-film solar cell.

As described in further detail herein, in accordance with embodiments of the methods of disclosure, thin-film solar cells may be produced by depositing one or more thin layers onto a semiconducting material. In general, all solar cells are considered photovoltaic, or as having the ability to convert light into electricity using semiconducting materials, regardless of whether the light source is natural or artificial. As used herein, the term “photovoltaic” refers to the production of electric current at the junction of two substances exposed to light. Typically, photovoltaic solar cells include a sheet of glass on the surface (or light-facing side) of the cell, allowing light to pass through but protecting the semiconductor material below. Different semiconducting materials used in photovoltaic cells can produce different results. Additionally, some solar cells can be made of only a single layer of light-absorbing material, also referred to as “single-junction”, or multiple layers of light-absorbing materials, also referred to as “multi-junction”. These layers of light-absorbing materials can be used to take advantage of various absorption and charge separation mechanisms. Typically, in thin-film solar cells, the semiconducting/absorber material is cadmium telluride (CdTe), copper indium gallium diselenide (CIGS), or amorphous thin-film silicon (a-Si, TF-Si). By way of non-limiting example, the semiconducting/absorber layer may be formed from a material comprising cadmium telluride (CdTe), and/or a ternary alloy of CdTe, such as CdSeTe, CdMgTe, CdZnTe or CdHgTe.

The several layers of various materials can be disposed on and around the semiconducting material; these materials can have a significant effect on the efficiency at which the solar cell produces energy. In at least one embodiment, materials can be disposed on all surfaces of the semiconducting material. In at least one example, oxide layers can be disposed on a front-surface and a back-surface of the semiconducting material. For example, oxide layers can be included in the solar cell device to act as a buffer layer and to assist in the transfer of electrons throughout the solar cell device. The method for producing the solar cell device as disclosed herein can include passivating an oxide layer on to the semiconducting/absorber layer. The term “passivate” as used herein means to coat a surface with an inert material in order to protect the surface from contamination. Oxides which can be used in the method disclosed herein can include, but are not limited to, copper aluminum oxide (CuAlO₃), strontium copper oxide (SrCu₂O₂), copper oxide (Cu₂O), magnesium zinc oxide (MgZnO), aluminum oxide (Al₂O₃), tin oxide (SnO₂), or any other suitable oxide. In one embodiment, a single oxide layer may be used to create a single junction cell as described herein. In an alternative embodiment, more than one oxide layer may be used to produce a multi-junction solar cell, as described herein.

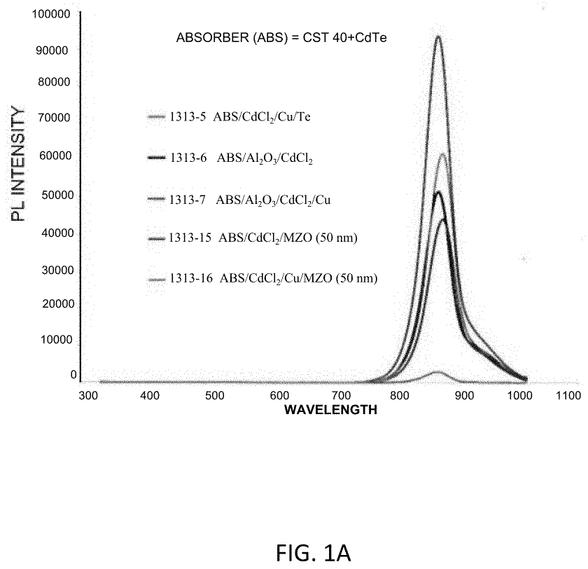

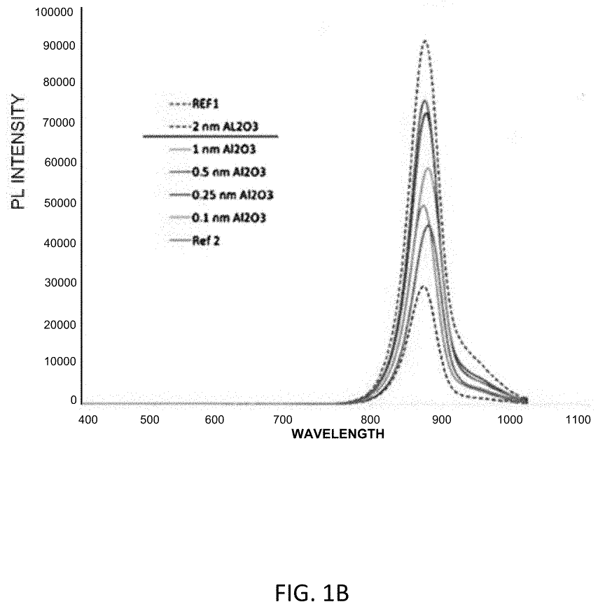

In exemplary embodiments of thin-film solar cells, the use of multiple oxide layers within a solar cell can increase the photoluminescence (PL) intensity of the resulting solar cell. The term “photoluminescence” as used herein refers to light emission from any form of matter after the absorption of photons (i.e., electromagnetic radiation). In creating a multi-junction solar cell device, the properties of the final device can be determined by the thickness of each layer and order in which the oxide layers are disposed onto the substrate material. For example, the band alignment of the oxide layers can be a critical component in determining the efficiency of the resulting solar cell device, as shown in FIGS. 1A and 1B. The phrase “band alignment” or “band offset” as used herein refers to the relative alignment of the energy bands at semiconductor heterojunctions. The term “heterojunction” as described herein refers to an interface that occurs between two layers or regions of dissimilar crystalline semiconductors.

Solar cells having different materials and different oxide layers can produce different PL intensities. For example, oxide layer thickness can also be a factor, the number and thickness of each of the oxide layers can be adjusted in order to achieve desired results. For example, thin oxide layers can be used in order to allow the charge to tunnel through the thicker layers of the oxide film, or through naturally occurring voids in the film which can allow for charge conduction.

FIG. 1A illustrates a graph indicating the PL intensity at specific wavelengths for five exemplary solar cells, 1313-5, 1313-6, 1313-7, 1313-15, and 1313-16. Each of the solar cells having an absorber layer (indicated in the FIG. as “ABS”), such as CST40 and CdTe, as well as various other materials. For example, FIG. 1A illustrates that solar cells having different materials, such as oxide layers, produce final products having different PL intensities. As shown, solar cell 1313-7, comprising an absorber of CST 40+ CdTe, Al₂O₃, a passivation treatment of cadmium chloride (CdCl₂), and a Cu doping, produces the highest PL intensity.

Moreover, FIG. 1B is a graph illustrating how the PL intensities is affected by oxide layer thickness in the same solar cell. Specifically, FIG. 1B illustrates various embodiments of the 1313-7 solar cell described above, each of the embodiments having a different Al₂O₃ layer thickness. As shown, the embodiments displayed in FIG. 1B have oxide layer thicknesses ranging from 0.1 nanometers (nm) to 2 nm, as well as two reference cells (REF 1 and REF 2). As illustrated, the thickness of each of the oxide layers can be adjusted in order to produce a solar cell having different properties. While FIG. 1B indicates the highest PL intensity is achieved with the thickest oxide layer, it would be obvious to those having skill in the art that oxide layer thicknesses can be adjusted to produce beneficial results, and thinner layers may be more beneficial to certain embodiments based on the other components present in the solar cell device. For example, thin oxide layers can be used in order to allow the charge to tunnel through the thicker layers of the oxide film, or through naturally occurring voids in the film which can allow for charge conduction.

As described above, various oxides can be used in the creation of solar cell devices. Each oxide can provide specific properties to the final solar cell device. In selecting which oxides are the most beneficial to the solar cell device, one factor that must be considered is energy band alignment. For example, some oxides can provide more favorable band-alignments than others. Oxides which can produce more favorable band-alignment can be deposited on the semiconducting material in thick layers. For example, the oxide layers may be deposited in thicknesses ranging from about less than about 1 nm to about 200 nm, 2 nm to 120 nm, 2 nm to about 100 nm, about 10 nm to about 100 nm, about 20 nm to about 100 nm, etc. In certain embodiments, under 1 nm thickness may also be efficiently utilized. In at least one example, favorable oxides can include, but are not limited to, CuAlO₃, SrCu₂O₂, and Cu₂O. In an alternative example, oxides can be deposited on the semiconducting material in thin layers. For example, the oxide layers may be deposited in thicknesses ranging from less than about 1 nm to as high as about 200 nm, about 1 nm to 20 nm, about 1 nm to about 10 nm, about 1 nm to about 5 nm, etc. Again, in certain embodiments, under 1 nm thickness may be efficiently utilized. However, while the band alignment may be less favorable than other oxides, the thin oxide layers can still be used to achieve desired properties in the final solar cell device.

In at least one example, oxides which can provide beneficial properties to a solar cell device when deposited in thin layers can include, but are not limited to, MgZnO and Al₂O₃. See, e.g., Kephart, Jason M., Anna Kindvall, Desiree Williams, Darius Kuciauskas, Pat Dippo, Amit Munshi, and W. S. Sampath. “Sputter-Deposited Oxides for Interface Passivation of CdTe Photovoltaics.” IEEE Journal of Photovoltaics 8, no. 2 (2018): 587-593. In yet another embodiment, oxides including, but not limited to, SnO₂, which can be used with or without necessary and sufficient doping with other elements in order to produce desired results. The doping in SnO₂ layer can be elements such as but not limited to Zn and Mg. Some results using this method have shown promising results. Deposition of such a layer can be included by glass manufacturer and that would reduce manufacturing time while increasing manufacturing output.

In at least one example, oxide layers can be disposed on a front-surface and a back-surface of an absorber layer. As used herein, the “front-surface” and “back-surface” oxide layers are described relative to the absorber/semiconducting material. The term “deposition” as used herein, refers to the act of depositing a first material onto a second material. As described above, the absorber layer can be a semiconducting material. The front-surface and back-surface oxide buffer can be used to improve the efficiency of the contact grids within the solar cell device.

In accordance with aspects of the disclosure, in at least one exemplary embodiment, a front-interface oxide layer of, e.g., Al₂O₃ can be disposed on a CdTe based solar cell at about 2 nm to about 20 nm, about 2 nm to about 10 nm, about 2 nm to about 5 nm, about 2 nm, about 5 nm, about 10 nm, etc. in thickness. In this regard, use of a thinner oxide layer at the back surface of the semiconductor layer, together with p+ layers has shown that thinner layers of the front-interface oxide layer (e.g., Al₂O₃) can be used to yield improvement in device performance. In certain aspects of the present disclosure, it was unexpectedly found that deposition of oxides such as, but not limited to Al₂O₃ at the front interface instead of more traditional oxides, e.g., MgZnO, can be used in accordance with aspects of the disclosure, to yield improvements in device performance. For instance such front interface oxides may achieve higher recombination lifetime while maintaining or improving the photovoltaic performance of the solar cell.

In the preparation of solar cells in accordance with the present disclosure, p+ layers can be deposited onto a substrate in order to assist in the increasing the efficiency of the solar cell device. In at least one embodiment, a solar cell can have a single p+ layer. In an alternative embodiment, a solar cell can have multiple p+ layers. The p+ layer described herein can include, but is not limited to, highly doped amorphous silicon. Silicon doping can be used to adjust the band-alignment of the solar cell in order to produce a cell having a more favorable arrangement for charge collection within the cell. For example, use of a p+ amorphous silicon layer disposed on an Al₂O₃ layer can improve the open-circuit voltage of the resulting solar cell. Deposition of oxides, including those described in detail above, at the front interface can be used to achieve a higher recombination lifetime and maintain the photovoltaic performance of the cell.

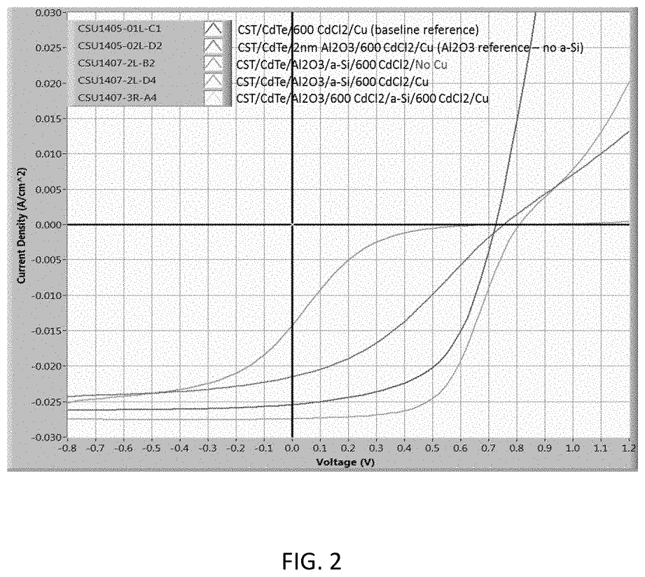

Solar cells made in accordance with the present disclosure have illustrated that a CdCl₂ passivation treatment and CuCl doping can be effectively used to produce a solar cell having improved features, as indicated in the graph provided in FIG. 1. As illustrated, the performance of the resulting solar cell device can be altered by merely changing the number of layers or the sequence in which treatment layers are applied. Specifically, FIG. 2 illustrates significant improvement in both the open-circuit voltage and efficiency of a solar cell having an Al₂O₃ and p+ a-Si layer deposited onto the semiconducting material after a CdCl₂ passivation and CuCl₂ doping treatment.

A chart relating to the graphical data is provided below in Table 1.

TABLE 1

| | | | V_{oc} | Fill Fac | J_{sc} | Eff | Cell Area | Vₘₚ | Jₘₚ |
|---|---|---|---|---|---|---|---|---|---|
| Run | Plate | Device | [mV] | [%] | [mA/cm²] | [%] | [cm²] | [mV] | [mA/cm²] |
| 1405 | 01L | C1 | 725 | 55.1 | 25.4 | 10.14 | 0.693 | 519 | 19.5 |
| 1405 | 02L | D2 | 754 | 33.9 | 21.5 | 5.49 | 0.704 | 400 | 13.7 |
| 1407 | 2L | B2 | 817 | 9.0 | 14.3 | 1.05 | 0.634 | 162 | 6.5 |
| 1407 | 2L | D4 | 808 | 56.4 | 27.4 | 12.48 | 0.629 | 533 | 23.4 |
| 1407 | 3R | A4 | 1175 | −69.4 | −0.0 | 0.00 | 0.695 | −800 | −0.0 |

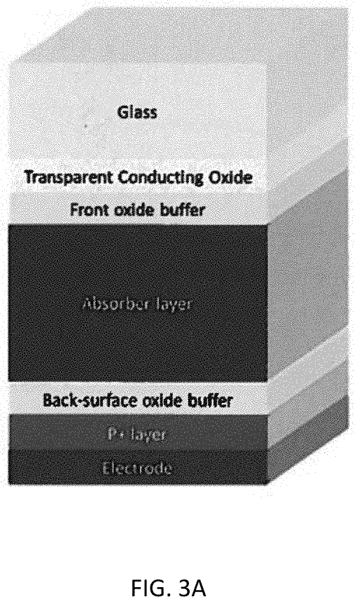

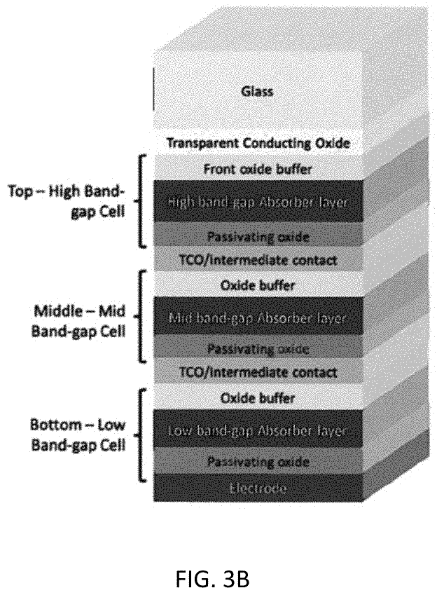

Examples of single junction and multi-junction solar cells are illustrated in FIGS. 3A and 3B. Specifically, FIG. 3A illustrates a schematic diagram of an exemplary single junction device. For the purposes of this example, the relative size of each of the layers illustrated in FIG. 3A are not considered to be to scale. The device of FIG. 3A is a single junction having a single oxide and p+ layer. Specifically, the exemplary solar cell device includes an electrode having a p+ layer disposed thereon, a back-surface oxide buffer, an absorber (semiconducting) layer, a front-surface oxide buffer, a transparent conducting oxide, and glass.

FIG. 3B illustrates a schematic diagram of an exemplary multi-junction solar cell device; as with FIG. 3A, for the purposes of this example the layers illustrated are not considered to be to scale. The device of FIG. 3B includes multiple band-gap cells, passivating oxides, and buffers. Specifically, the solar cell device includes an electrode having three different band-gaps (top, middle, and bottom), a transparent conducting oxide (TCO), and glass. Each of the three gaps includes a passivating oxide, a semiconducting layer/absorber and an oxide buffer. The bottom, or low band, gap cell includes a passivating oxide, having a low band-gap absorber layer and oxide buffer disposed thereon; the middle, or mid band, gap cell also includes a passivating oxide having a mid band-gap absorber layer and oxide buffer disposed thereon; and the top, or high band, gap cell includes a passivating oxide, high band-gap absorber layer, and front oxide buffer disposed thereon. A TCO/intermediate contact layer can be located between the bottom and middle cells, as well as between the middle and top cells.

In at least one embodiment, a layer of zinc telluride (ZnTe) can be deposited on the back-surface of the solar cell device. The ZnTe layer can assist in producing favorable band alignment throughout the cell. In said example, the solar cell device can also be doped with a dopant, such as copper, to improve PL intensity and reduce voltage deficit within the cell. In at least one example, solar cell devices having a ZnTe layer can be passivated with zinc chloride (ZnCl₂), to produce a solar cell showing superior energy performance. Passivation treatments as described herein including, but not limited to, those done with materials such as CdCl₂, can be used to produce high efficiency thin-film solar cells, and can be re-optimized based on the incorporation of one or more oxide layers. Furthermore, solar cells produced in accordance with the present disclosure, have been shown to have a higher efficiency when CdCl₂ is passivated onto the oxide layer.

Additionally, in at least some embodiments, copper can be used to dope the cadmium telluride (CdTe) based thin-film solar cells. The CuCl doping treatment can be used to dope the bulk material and form a back-surface contact on the semi-conducting material. Such contact can assist in achieving a higher efficiency by moving all, or part, of the contact grids to the rear of the solar cell device. While a copper dopant is described in more detail, it would be obvious to those having skill in the art that other dopants can be used to treat the solar cell device. Suitable dopants can include, but are not limited to, nitrogen, phosphorus, arsenic, antimony, and bismuth. The dopants described herein can be used to dope the bulk material of the semiconductor prior to the deposition of an oxide layer. The combination of doping the semiconducting material prior to deposition of an oxide layer, after the deposition of an oxide layer, and/or after the passivation treatment of the semiconducting material can improve the efficiency of the resulting solar cell.

Moreover, both doping and passivation treatments can have a significant impact on the electrodes present within the solar cell. As such, the particular electrode used within the solar cell must be considered when selecting materials to use in either a dopant or a passivation treatment. Electrodes that can be altered by doping and passivation treatments as described herein can include transparent, translucent, and opaque electrodes. Suitable electrodes can be metallic or non-metallic in nature. Specifically, materials that can be used as described herein can include, but are not limited to, metals (including, but not limited to, nickel, gold, and aluminum), semi-conducting materials or metalloids (including, but not limited to, tellurium), and non-metals (including, but not limited to, nickel oxide, doped tin oxide, and graphite).

As described with respect to FIGS. 3A-3B, the methods described herein can be used to produce both single junction and multi-junction solar cells. Multi-junction solar cells produced in accordance with the present disclosure can include both high band-gap solar cells and low band-gap solar cells. The high and low band-gap solar cells can have similar device structures as those described in detail above. In addition to producing high and low band-gap solar cells, the methods described herein can be used separately or in tandem in order to achieve an increased solar cell output.

For example, higher band-gap solar cells can be fabricated using alloy compositions including, but not limited to, cadmium magnesium tellurium (CdₓMg₁₋ₓTe) and cadmium zinc tellurium (CdₓZn₁₋ₓTe). The oxide layers, doping treatments, and passivation treatments described above can be used where appropriate to optimize the materials present in the solar cell to produce high efficiency thin-film solar cells having a higher band-gap.

In an alternative example, a lower band-gap solar cell can be fabricated using an alloy compositions including, but not limited to, cadmium magnesium tellurium (CdₓHg₁₋ₓTe). As described above, various materials can be used to optimize the solar cell device by applying oxide layers, doping treatments, and passivation treatments to produce a high efficiency thin-film solar cell having lower band-gap.

In yet another alternative example, low band-gap, mid-band gap, and high band-gap cell structures can be fabricated in tandem using a variety of intermediate contacts in order to form a multi-junction solar cell having a higher efficiency than each of the individual solar cells within the multi-junction structure. As described in detail above, an example of an exemplary multi-junction solar cell is illustrated in FIG. 3B.

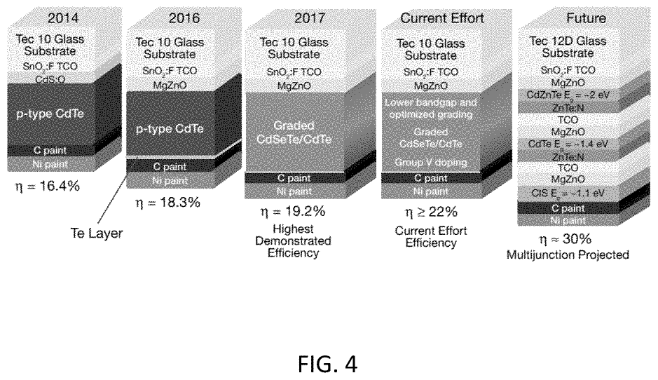

The processes and methods described herein can be shown to increase the efficiency of solar cells, as indicated in FIG. 4. Specifically, FIG. 4 illustrates a range of efficiencies from past functional solar cells to potential solar cells which can be created in the future using the methods described herein. Specifically, in 2014 an efficiency of 16.4% was possible; in 2016 it was increased to 18.3%. Using the methods and materials disclosed herein it has been demonstrated that a CdTe based thin-film solar cells having an efficiency of 19% was achieved. See., e.g., Munshi, Amit H., Jason Kephart, AliAbbas, John Raguse, Jean-Nicolas Beaudry, Kurt Barth, James Sites, John Walls, and Walajabad Sampath. “Polycrystalline CdSeTe/CdTe Absorber Cells with 28 mA/cm2 Short-Circuit Current.” IEEE Journal of Photovoltaics 8, no. 1 (2018): 310-314. The increase in efficiency can be traced to at least three major advances within the basic cell structure of a CdTe PV. For example, replacing a traditional cadmium sulfide (CdS) layer with a magnesium-doped zinc oxide layer significantly changed the properties of the resulting solar cell device. Specifically, MgZnO has a higher bandgap than CdS, allowing for more photons to reach the CdTe absorber layer. Additionally, MgZnO has a conduction-band offset that can help reduce interfacial recombination, preserving the voltage. Second, the incorporation of a Te layer at the back of the CdTe layer. The inclusion of a second Te layer can allow the solar cell device to yield an improved contact and higher efficiency. In accordance with aspects of the disclosure, it was found that CdTe thin-film solar cell efficiency can be improved to over 21% with open-circuit voltage of over 1V.

This improvement is indicated in the transition from the 2014 to the 2016 solar cell of FIG. 4. Such addition was able to produce an efficiency increase of nearly 2%. Finally, the introduction of an alloy layer of CdTe and CdSe, or CdSeTe, in front of the CdTe layer has allowed for significant improvements. Specifically the CdSeTe layer has a smaller bandgap, enabling it to produce more currently. Additionally, the CdSeTe layer has a longer recombination lifetime than CdTe and can form an electric field in the favorable direction where the cell transitions from CdTe to CdSeTe. A cell made in accordance with this feature is indicated in the 2017 cell of FIG. 4, which is an exemplary embodiment of the present disclosure, indicating an increase to 19.2% efficiency.

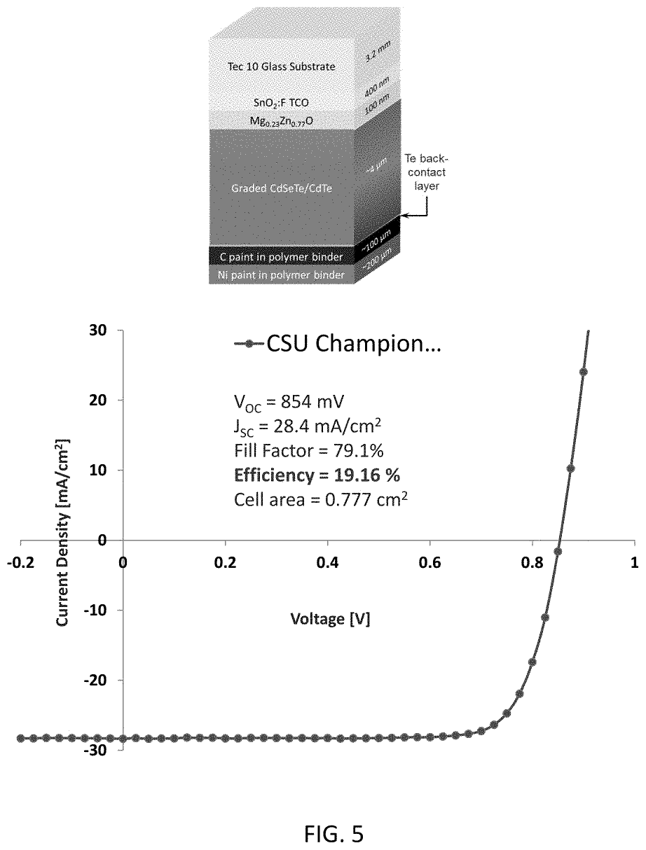

An enlarged view of the 2017 cell is shown in FIG. 5, along with a chart indicating the voltage and current density of the cell. As shown, the cell can produce a voltage of above about 0.8. As the methods described herein are improved, efficiencies above 20% are predicted to be possible, as indicated in FIG. 4.

The processes described herein can be performed using various methods including, but not limited to, radio frequency (RF) sputtering, magnetron sputtering, evaporation, sublimation, co-sublimation, close-space sublimation, metal organic chemical vapor deposition (MOCVD), chemical vapor deposition, physical vapor deposition, diffusion, atomic layer deposition, molecular beam epitaxy (MBE), electroplating, dip coating, and spin coating. In an alternative example, one or more of the above described processes can be performed by a supplier on a preceding process including, but not limited to, deposition of layers during manufacturing of glass or other substrate/superstrate.

The following example is provided to illustrate the subject matter of the present disclosure. The example is not intended to limit the scope of the present disclosure and should not be so interpreted.

### Example

A CdTe solar cell can include a front interface oxide layer of Al₂O₃, the oxide layer being about 2 nanometers (nm) in thickness. A solar cell having such an oxide layer has been shown to have increased performance, stability, and manufacturability perspectives. The use of Al₂O₃ has been shown to form a double heterojunction device having a high recombination lifetime. A solar cell device as described in this example has been shown to have a lifetime of over 1.4 microseconds (μs), as compared to the 10 nanoseconds (ns) lifetime of a solar cell without the described Al₂O₃ layer. As such, it has been shown that the Al₂O₃ layer provides a resistive buffer layer which prevents charges from being collected within the solar cell.

Additionally, a solar cell device having a thin oxide layer deposited on the back-surface of the semiconducting material has also shown significant improvements in performance. In at least one example, the back-surface oxide layer can also be an Al₂O₃ layer. An exemplary diagram of a solar cell device in accordance with this disclosure is shown in FIG. 3A (indicating the presence of an oxide buffer on both the front and back surfaces of the semiconducting material).

In at least one example, a solar cell having an oxide layer of Al₂O₃ can produce improved performance qualities, when compared to a solar cell having an MgZnO oxide layer. Additionally, Al₂O₃ has been shown to provide stability over long periods of time, as well as in the presence of high operating temperatures and humidity.

What is claimed is:

1. A thin-film solar cell with improved efficiency, the thin-film solar cell comprising:
a semiconducting/absorber layer;
at least one p+ layer; and
one or more oxide layers passivated onto at least one surface of the semiconducting/absorber layer;
wherein the thin-film solar cell exhibits an efficiency of at least 10%.

2. The thin-film solar cell of claim 1, wherein at least one of the oxide layers is passivated onto the front-surface of the semiconducting/absorber layer, and the at least one oxide layer on the front-surface of the semiconducting/absorber layer is formed from aluminum oxide (Al₂O₃).

3. The thin-film solar cell of claim 2, wherein the at least one oxide layer on the front-surface of the semiconducting/absorber layer is about 2 nanometers (nm) to 10 nm in thickness.

4. The thin-film solar cell of claim 2, wherein the thin-film solar cell comprises at least one additional oxide layer in addition to the at least one oxide layer on the front-surface of the semiconducting/absorber layer.

5. The thin-film solar cell of claim 4, wherein the at least one additional oxide layer is passivated onto the back-surface of the semiconducting/absorber layer.

6. The thin-film solar cell of claim 5, wherein the at least one oxide layer on the back-surface of the semiconducting/absorber layer is about 2 nm to 100 nm in thickness.

7. The thin-film solar cell of claim 6, wherein the at least one oxide layer on the back-surface of the semiconducting/absorber layer is aluminum oxide (Al₂O₃).

8. The thin-film solar cell of claim 1, wherein the semiconducting/absorber layer is formed from a material comprising cadmium telluride (CdTe) and/or a ternary alloy of CdTe comprising CdSeTe, CdMgTe, CdZnTe or CdHgTe.

9. The thin-film solar cell of claim 1, wherein the at least one oxide layer is formed from a material selected from the group consisting of copper aluminum oxide (CuAlO₃), strontium copper oxide (SrCu₂O₂), copper oxide (Cu₂O), magnesium zinc oxide (MgZnO), aluminum oxide (Al₂O₃), and tin oxide (SnO₂).

10. The thin-film solar cell of claim 1, wherein prior to passivating the at least one oxide layer onto at least one surface of the semiconducting/absorber layer, the at least one surface of the semiconducting/absorber layer is doped using a dopant selected from the group consisting of nitrogen, phosphorus, arsenic, antimony, and bismuth, and copper.

11. The thin-film solar cell of claim 10, wherein the semiconducting/absorber layer is doped with copper.

12. The thin-film solar cell of claim 10, wherein the semiconducting/absorber layer is doped to produce both a front-surface contact and a back-surface contact.

13. The thin-film solar cell of claim 1, further comprising a telluride layer disposed beneath the semiconducting/absorber layer.

14. The thin-film solar cell of claim 10, wherein the thin-film solar cell comprises a plurality of oxide layers.

15. The thin-film solar cell of claim 14, wherein at least one of the plurality of oxide layers are formed from magnesium zinc oxide (MgZnO).

16. The thin-film solar cell of claim 14, wherein the plurality of oxide layers produce a high-band gap cell, a mid band-gap cell, and a low-band gap cell.

17. A method for producing a thin-film solar cell with improved efficiency, the method comprising:
providing an semiconducting bulk material;
depositing one or more one oxide layers onto at least one surface of the semiconducting bulk material;
passivating the deposited one or more oxide layer; and
doping the semiconducting bulk material with a dopant to thereby form a semiconducting/absorber layer;
wherein the doping of the semiconducting bulk material after depositing and passivating the one or more oxide layers produces a thin-film solar cell with an efficiency of at least 10%.

18. The method of claim 17, wherein at least one of the oxide layers is passivated onto the front-surface of the semiconducting material, and the at least one oxide layer on the front-surface of the semiconducting material comprises aluminum oxide (Al₂O₃).

19. The method of claim 18, wherein the at least one oxide layer on the front-surface of the semiconducting/absorber layer is about 2 nanometers (nm) to 10 nm in thickness.

20. The method of claim 18, wherein the thin-film solar cell comprises at least one additional oxide layer in addition to the at least one oxide layer on the front-surface of the semiconducting/absorber layer.

21. The method of claim 20, wherein the at least one additional oxide layer is passivated onto the back-surface of the semiconducting/absorber layer.

22. The method of claim 20, wherein the at least one oxide layer on the back-surface of the semiconducting/absorber layer is about 2 nm to 100 nm in thickness.

23. The method of claim 21, wherein the at least one oxide layer on the back-surface of the semiconducting/absorber layer is aluminum oxide (Al₂O₃).

24. The method of claim 17, wherein the semiconducting bulk material is formed from a material comprising cadmium telluride (CdTe) and/or a ternary alloy of CdTe comprising CdSeTe, CdMgTe, CdZnTe or CdHgTe.

25. The method of claim 17, wherein the dopant used to dope the semiconducting bulk material is selected from the group consisting of nitrogen, phosphorus, arsenic, antimony, and bismuth, and copper.

26. The method of claim 25, wherein the dopant is used to create a front-surface contact or a back-surface contact on the semiconducting material.

27. The method of claim 17, wherein the one or more one oxide layers are formed from a material selected from the group consisting of copper aluminum oxide (CuAlO₃), strontium copper oxide (SrCu₂O₂), copper oxide (Cu₂O), magnesium zinc oxide (MgZnO), aluminum oxide (Al₂O₃), and tin oxide (SnO₂).

28. The method of claim 17, further comprising depositing multiple oxide layers onto at least one surface of the thin-film solar cell to produce a plurality of oxide layers.

29. The method of claim 28, wherein the plurality of oxide layers produce a high band-gap cell, a mid band-gap cell, and a low band-gap cell.

30. The method of claim 17, further comprising disposing a telluride layer below the semiconducting material.
